(19) United States
(12) Patent Application Publication
(10) Pub. No.: US 2025/0332687 A1
(43) Pub. Date: Oct. 30, 2025

(54) NOZZLE ASSEMBLY FOR A FLUID RECOVERY SYSTEM

(71) Applicant: Applied Materials, Inc., Santa Clara, CA (US)

(72) Inventors: Robert NAVASCA, Redwood City, CA (US); Chetan Kumar MYLAPPANAHALLI NARASINGAIAH, Bangalore (IN); Colin John DICKINSON, San Jose, CA (US)

(21) Appl. No.: 18/646,597

(22) Filed: Apr. 25, 2024

(51) Int. Cl. B24B 57/02; H01L 21/306

(52) U.S. Cl. CPC B24B 57/02; H01L 21/30625

(57) ABSTRACT

The present disclosure generally relates to a nozzle assembly, a polishing system, and a method for operating the polishing system. The nozzle assembly includes an upper manifold attached to a top surface of a platen and a lower manifold attached to a bottom surface of the platen. The upper manifold secures a slurry-collecting line having a slurry-collecting tube and a cleaning line having a cleaning tube. The cleaning line has a waste-collecting valve and a cleaning valve that are secured by the lower manifold. The polishing system includes a polishing platen to support a polishing pad; a gutter disposed around the polishing platen; and a slurry-collecting line comprising a slurry-collecting tube coupled with a slurry-collecting valve, the slurry-collecting tube extending into the gutter, the slurry-collecting line being configured to remove slurries out of the gutter in a slurry-collecting mode and dispense a flushing agent in a flushing mode.

### BACKGROUND

### Field

Embodiments described herein generally relate to a polishing system for processing semiconductor substrates, and more particularly, to a polishing system having a plurality of plumbing lines for recovering slurry and/or cleaning a slurry conduit in a chemical mechanical polishing process.

### Description of the Related Art

Chemical mechanical polishing (CMP) is commonly used to planarize and polish a substrate. A CMP process may include removing materials from the surface of the substrate by a polishing pad in the presence of a polishing fluid. Commonly used polishing fluids include highly engineered abrasive particle-containing slurries, e.g., colloids or suspensions, reactive liquid (abrasive-free) slurries, and abrasive-free or reduced-abrasive polishing fluids used a polishing pad having abrasive particles disposed therein.

The costs of CMP polishing fluids are high. Thus, many CMP systems may have a recovery system to collect CMP used fluids during the CMP process for reuse. Cross-contamination of the CMP fluids typically requires additional treatments during a recovery process. However, the conventional process to collect the used CMP fluid is prone to cause cross-contaminations, causing the reuse of polishing fluids very expensive.

Thus, there is a need in the art for an improved polishing system.

### SUMMARY

Disclosed herewith are a manifold assembly, a polishing system having the manifold assembly, and a method for operating the polishing system. In an example, the nozzle assembly includes an upper manifold having a cleaning nozzle, a slurry-collecting nozzle, and a slurry-collecting valve coupled to an upper bracket, the slurry-collecting nozzle being coupled with the slurry-collecting valve; and a lower manifold disposed under the upper manifold and having a waste-collecting valve and a cleaning valve coupled to the lower bracket. The cleaning nozzle is coupled with the waste-collecting valve and the cleaning valve of the lower manifold.

In an example, the polishing system includes a polishing platen to support a polishing pad, a gutter disposed around the polishing platen, and a slurry-collecting line having a slurry-collecting tube coupled with a slurry-collecting valve. The slurry-collecting tube extends into the gutter, and the slurry-collecting line is configured to remove slurries out of the gutter in a slurry-collecting mode and dispense a flushing agent in a flushing mode. The polishing system may also include a cleaning line having a cleaning tube and coupled with one or more valves; the cleaning tube extending into the gutter, the cleaning line being configured to dispense a cleaning agent into the gutter and then remove the cleaning agent out of the gutter.

In another example, the polishing system includes a polishing pad configured to abrade a substrate; a first platen disposed under the polishing pad; a slurry-dispensing arm configured to dispense a polishing fluid toward the first platen; a slurry-collecting gutter disposed around the platen; a base plate disposed under the platen; and a nozzle assembly. The nozzle assembly includes an upper manifold coupled to a top surface of the base plate and a lower manifold coupled to a bottom surface of the base plate. The upper manifold includes a cleaning nozzle, a slurry-collecting nozzle, and a slurry-collecting valve coupled to an upper bracket, the slurry-collecting nozzle being coupled with the slurry-collecting valve. The lower manifold includes a waste-collecting valve and a cleaning valve coupled to the lower bracket. The cleaning nozzle is coupled with the waste-collecting valve and the cleaning valve of the lower manifold.

In another example, the method of polishing a substrate includes dispensing a polishing fluid toward a platen, the polishing fluid including a slurry; collecting the polishing fluid from a collecting gutter by using a slurry-collecting nozzle that extends into the collecting gutter, the collecting gutter being disposed around the platen and rotating with the platen; dispensing a first flow of nitrogen via the slurry-collecting nozzle for a predetermined period when dispensing the polishing fluid is stopped; dispensing a cleaning agent toward the platen, the cleaning agent comprising DI water and/or citric acid; dispensing a second flow of nitrogen via the slurry-collecting nozzle before dispensing the cleaning agent is stopped; and collecting the cleaning agent from the collecting gutter by using a cleaning nozzle that extends into the collecting gutter. The cleaning nozzle and the slurry-collecting nozzle are disposed side by side.

To facilitate understanding, identical reference numerals have been used, where possible, to designate identical elements that are common to the figures. It is contemplated that elements and features of one embodiment may be beneficially incorporated in other embodiments without further recitation.

### BRIEF DESCRIPTION OF THE DRAWINGS

So that the manner in which the above-recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 illustrates a schematic side view of a polishing system having a nozzle assembly, according to an embodiment.

FIG. 2 illustrates a schematic perspective view of a collecting gutter in FIG. 1, according to an embodiment.

FIG. 3 illustrates a schematic cross-sectional view of the collecting gutter in FIG. 1, according to an embodiment.

FIG. 4 illustrates a schematic perspective view of a nozzle assembly, according to an embodiment.

FIG. 5 illustrates a schematic plumbing diagram of a polishing system, according to an embodiment.

FIG. 6 illustrates a schematic partial top view of a polishing system, according to an embodiment.

FIG. 7 illustrates a method for operating the polishing system, according to an embodiment.

In order to facilitate understanding, identical reference numerals have been used where possible to designate identical elements that are common to the figures. It is contemplated that the elements and features of each embodiment may be beneficially incorporated into the other embodiments without further recitation.

### DETAILED DESCRIPTION

Embodiments of the present disclosure generally provide a manifold assembly for a polishing system. The manifold assembly includes a slurry-collecting nozzle of a slurry-collecting system that is configured to collect used polishing fluids or slurries from a collecting gutter. The manifold assembly also includes a cleaning nozzle of a clean/dry system configured to dispense a cleaning agent or a dry agent to the collection gutter and collect the cleaning agent or the dry agent. The slurry-collecting system and the cleaning system are separated and do not fluidly communicate with each other. The slurry-collecting nozzle is configured to dispense a cleaning agent when the used cleaning agent is being collected by the collecting agent. The slurry-collecting nozzle and the cleaning nozzle may be arranged side by side in the collecting gutter to save space.

With dedicated nozzles and systems for collecting the cleaning agent and the used CMP fluids, contamination of the slurry-collecting system is reduced. Furthermore, the slurry-collecting nozzle further reduces any contamination by dispensing a cleaning agent while the cleaning nozzle collects used cleaning agents in the collection gutter.

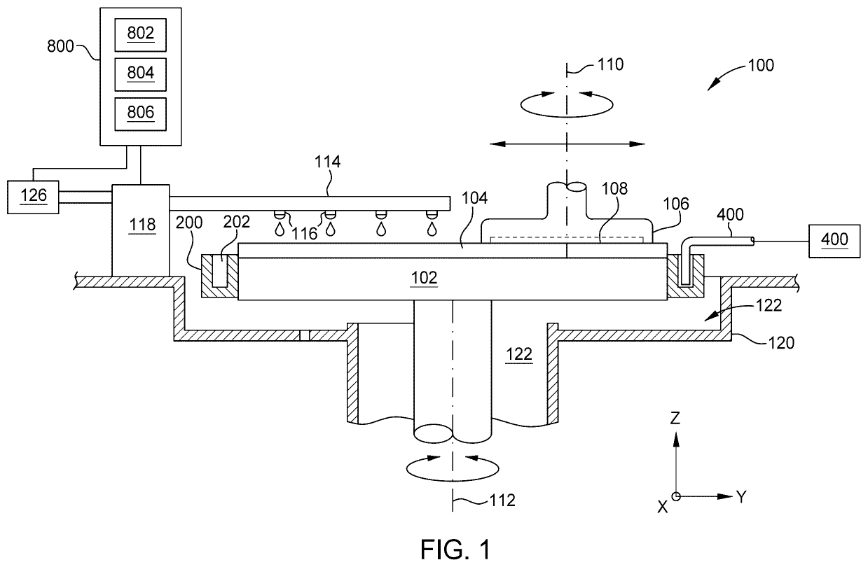

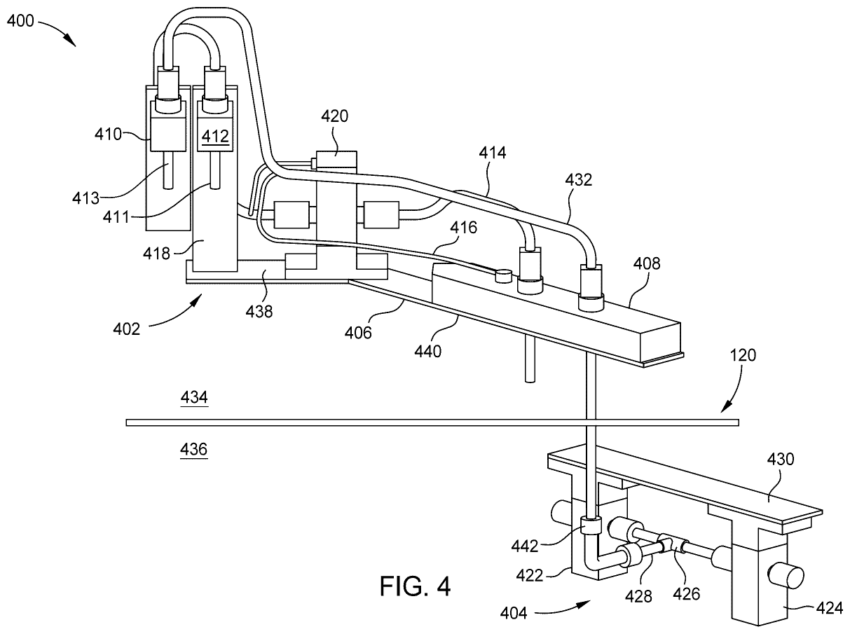

FIG. 1 illustrates a schematic side view of a polishing system 100, according to one embodiment. The polishing system 100 includes a nozzle assembly 400 as shown in FIG. 4. The nozzle assembly 400 is used for collecting used CMP fluids from a collecting gutter and cleaning the collecting gutter.

The polishing system 100 includes one or more platens 102, a polishing pad 104 secured to the platen, a substrate carrier 106 disposed above the platen 102 and facing the polishing pad 104, and a collecting gutter 200 used to collect fluids and slurries used during polishing and cleaning processes. A substrate 108 is retained by the substrate carrier 106 during a polishing process. The platen 102 may rotate about an axis 112 during the polishing process.

The polishing system 100 further includes a fluid-dispensing arm 114 positioned over the platen 102. A polishing fluid source 126 delivers polishing fluids, such as polishing fluid additives, cleaning fluids, deionized (DI) water or other suitable fluids, to the fluid-dispensing arm 114, which can be dispensed onto the polishing pad 104 via nozzles 116 positioned in the fluid-dispensing arm 114. The fluid-dispensing arm 114 is coupled to an actuator 118, which positions the fluid-dispensing arm 114 over the platen 102 by swinging the fluid-dispensing arm 114 over the platen 102. The actuator 118 is disposed on a base plate 120 placed below the platen 102. The base plate 120 may also include a drain 122 configured to discharge any fluid or slurry not caught by the collecting gutter 200. A system controller 800, controls operations of the actuator 118, the fluid-dispensing arm 114, the nozzle assembly 400, and other components of the polishing system 100.

To polish the substrate 108, the substrate carrier 106 urges a surface of the substrate 108 against the polishing pad 104, which rotates about a carrier axis 110. The rotating substrate carrier 106 may sweep back and forth from an inner diameter to an outer diameter of the platen 102 to, in part, reduce uneven wear of the polishing pad 104.

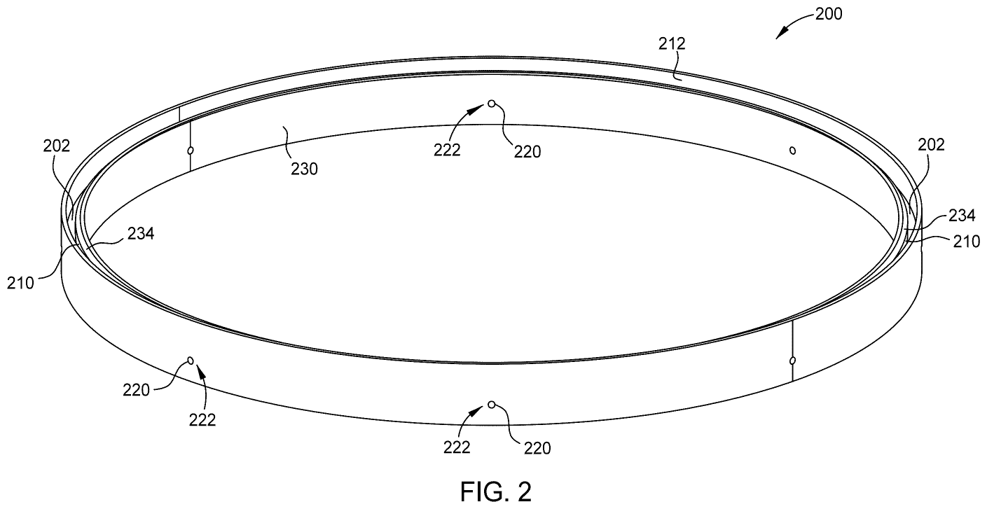

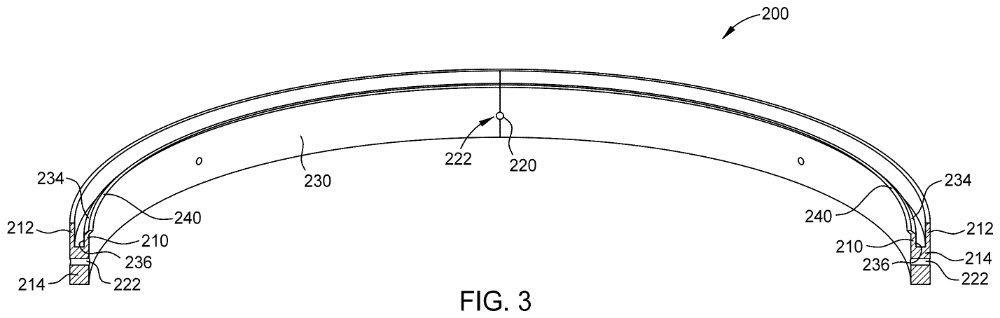

Referring to FIGS. 2 and 3, the collecting gutter 200 is sized to surround and abut the platen 102. The collecting gutter 200 includes an inner wall 210, an outer wall 212, and a base portion 214. The outer wall 212 is disposed radially outward from the inner wall 210. The base portion 214 connects the inner wall 210 to the outer wall 212. The inner wall 210, the outer wall 212, and the base portion 214 collectively define a trough 202, which is shown in FIG. 1 as having a U-shaped profile in cross section, although any suitable cross-sectional shape may be used. The components of the collecting gutter 200, i.e., the inner wall 210, the outer wall 212, and the base portion 214, are formed of a polishing fluid chemically resistant polymer having a hydrophobic surface. Examples of suitable polymers include fluorine-containing polymers (fluoropolymers), such as perfluoroalkoxy (PFA), fluorinated ethylene propylene (FEP), polytetrafluoroethylene (PTFE) commercially available as TEFLON® from DuPont, or combinations thereof. In some embodiments, the base portion 214 of the collecting gutter 200 is an annular ring that surrounds the platen 102 and is fixedly coupled thereto. The base portion 214 is configured to have a plurality of holes 222 configured to receive a plurality of fasteners 220. The fasteners couple the collecting gutter 200 to the platen 102 such that the collecting gutter 200 rotates about the platen axis 112 with the platen 102.

The collecting gutter 200 collects the polishing fluid which is spun radially outward from the rotating polishing pad 104 and the platen 102 due to the centrifugal force imparted thereto. The inner wall 210 and the outer wall 212 each extend from the base portion 214 in the Z-direction by a height H(1), although different heights for each of the walls may be used. The radially inward facing surface 230 of the collecting gutter 200 is further defined by an arc radius which is equal to an arc radius of the platen 102 that the collecting gutter 200 is sized to surround. This allows for all of the polishing fluid to flow radially outward from the surface of the platen 102 into the trough 202.

FIG. 4 illustrates a schematic perspective view of the nozzle assembly 400, according to an embodiment. The nozzle assembly 400 includes an upper manifold 402 and a lower manifold 404 separated by the base plate 120. The platen 102 and the upper manifold 402 are disposed at the same side of the base plate 120. The lower manifold 404 is disposed at the opposite side of the base plate 120 relative to the upper manifold 402. The placement of the lower manifold 404 at a different side can save space for the upper manifold 402 since the polishing system 100 has limited space for the platen 102 and the upper manifold 402.

In an embodiment, the upper manifold 402 is attached to a top surface 434 of the base plate 120, while the lower manifold 404 is attached to a bottom surface 436 of the base plate 120 at a location right under the upper manifold 402, which can minimize the amount of plumbing lines used for coupling with the upper manifold 402. The lower manifold 404 may be attached to other suitable locations under the base plate 120 by using additional plumbing lines to couple with the upper manifold 402.

In an embodiment, the upper manifold 402 includes a plurality of nozzles, such as a slurry-collecting nozzle 412 and a cleaning nozzle 410. The cleaning nozzle 410 and the slurry-collecting nozzle 412 are configured to extend into the trough 202 of the slurry-collecting gutter 200 for dispensing and collecting fluids/slurries. The slurry-collecting nozzle 412 includes a collecting tube 411 that extends into the trough 202 and is configured to draw used polishing fluids and slurries out of the trough 202 by vacuum. The cleaning nozzle 410 includes a cleaning tube 413 that extends into the trough 202 and is configured to collect a cleaning agent from the slurry-collecting gutter 200 that is dispensed by the cleaning nozzle 410 or the fluid-dispensing arm 114 (shown in FIG. 1). The operation of the slurry-collecting nozzle 412 and the cleaning nozzle 410 is configured to reduce the contamination of the slurry-collecting nozzle 412, which is part of a slurry-collecting system.

The upper manifold 402 further includes a bracket 406, a holding block 408, and a slurry-collecting valve 420. The bracket 406 is substantially horizontal and attached to the base plate 120. The bracket 406 functions as a reinforcement to secure other parts, such as the nozzles, plumbing lines, and valves. As the nozzles, plumbing lines, and valves are positioned around the outer perimeter of the circular collecting gutter 200, the bracket 406 may be formed by a plurality of segments angularly coupled with each other to follow the perimeter of the gutter 200. As shown in FIG. 4, the bracket may include a first segment 438 and a second segment 440. In embodiment, the first segment 438 and the second segment 440 form an obtuse angle at a side facing the collecting gutter 200.

The nozzles, plumbing lines, and valves are attached to various locations of the bracket 406. For example, the cleaning nozzle 410 and the slurry-collecting nozzle 412 are attached to the bracket 406 via a vertical bracket 418. The vertical bracket 418 is located at an end of the bracket 406 and extends away from the bracket 406. The holding block 408 is attached to another end of the bracket 406 and configured to secure a plurality of plumbing lines of the upper manifold 402. The plurality of plumbing lines include an upper cleaning line 432 coupled with the cleaning nozzle 410 and secured by the holding block 408. An upper slurry-collecting line 414 coupled with the slurry-collecting valve 420 is also secured by the holding block 408. The slurry-collecting valve 420 is attached to the bracket 406 at a location that is between the vertical bracket 418 and the holding block 408. The holding block 408 also secures a controlling line 416 coupled with and configured to control the slurry-collecting valve 420. In an embodiment, the controlling line 416 is configured to close or open the slurry-collecting valve 420 via an electromagnetic force or a pneumatic force.

In an embodiment, the slurry-collecting nozzle 412, the slurry-collecting valve 420, and the upper slurry-collecting line 414 are configured to draw slurry out of the trough 202 during a polishing process. The slurry-collecting nozzle 412, the slurry-collecting valve 420, and the upper slurry-collecting line 414 are configured to dispense a flushing agent during a cleaning process to reduce any potential contamination of the slurry-collecting nozzle 412. The cleaning process may be used to clean the collecting gutter 200, the platen 102, or other part of the polishing system 100.

In an embodiment, the cleaning nozzle 410 and the upper cleaning line 432 are configured to dispense a cleaning agent during a cleaning process. The cleaning agent may include DI water, nitrogen, citric acid, and/or other chemical.

The lower manifold 404 includes a bracket 430 configured to be attached to the base plate 120. The lower manifold 404 further includes a waste-collecting valve 422 and an agent-dispensing valve 424, both attached to the bracket 430. Both the waste-collecting valve 422 and the agent-dispensing valve 424 are coupled to a lower cleaning line 428 via a T connector 426. The lower cleaning line 426 is coupled with an elbow connector 442, which is coupled with the upper cleaning line 432 that extends through the holding block 408. The agent-dispensing valve 424 is configured to deliver the cleaning agent to the cleaning nozzle, while the waste-collecting valve 422 is configured to draw the used cleaning agent from the trough 202.

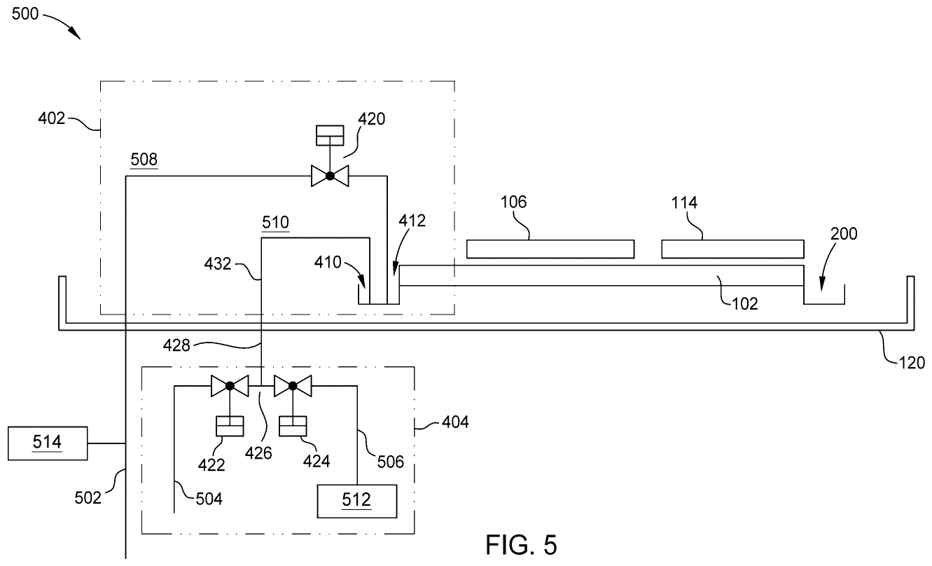

FIG. 5 illustrates a plumbing diagram 500 of the polishing system 100, according to an embodiment. The plumbing diagram 500 shows a slurry-collecting line 508 that includes the slurry-collecting nozzle 412, the slurry-collecting valve 420, and a slurry-discharging tube 502 configured to discharged collected fluids/slurries into a container (not shown). The slurry-discharging tube 502 may be coupled with a pump (not shown) configured to generate vacuum in the slurry-collecting system. In an embodiment, the slurry-collecting valve 420 is coupled with a flushing agent source 514 configured to supply a flushing agent to the slurry-collecting line 508. The flushing agent may include nitrogen or DI water. The agent source 514 may include a pump (not shown) that is configured to push the flushing agent through the slurry-collecting nozzle 412. The slurry-collecting line 508 is configured to dispense the flushing agent during a time when the cleaning nozzle 410 is activated to dispense materials to or collect materials to the collecting gutter 200.

The plumbing diagram 500 also shows a cleaning line 510 that includes the cleaning nozzle 410, the upper cleaning line 432, the lower cleaning line 428, the T connector 426, the waste-collecting valve 422, the agent-dispensing valve 424, a waste-discharging tube 504, and an agent-supply line 506. The waste-discharging tube 504 is configured to discharge used agents into a container (not shown). The waste-discharging tube 504 may be coupled with a pump (not shown) configured to generate vacuum. The agent-supply line 506 is coupled with a cleaning agent source 512 and is configured to deliver the cleaning agent from the agent source to the agent-dispensing valve 424. The agent source 512 may include a pump (not shown) capable of generating adequate pressure to push a cleaning agent through the cleaning line 510. For example, the agent-supply line 506 may deliver DI water to the cleaning nozzle 410 to clean the collecting gutter 200 or deliver nitrogen to the cleaning nozzle 410 to dry the collecting gutter.

In an embodiment, the slurry-collecting line 508 and the cleaning line 510 are separated and not fluidly communicated with each other. Both the cleaning nozzle 410 and the slurry-collecting nozzle 412 side by side and extends into the trough 202 of the collecting gutter 200.

A substrate polishing cycle may include a plurality of processes, such as a pre-clean process, a polishing process, a post-clean process, and any other process. Operations of various systems of the plumbing diagram 500 during each process will be described in the following paragraphs.

During the pre-clean process, the fluid-dispensing arm 114 dispenses chemicals and DI waters to clean the platen 102. In an embodiment, the operation of the slurry-collecting line 508 may be divided into a plurality of operating modes, including a slurry-collecting mode, a flushing mode, or any other mode. During the flushing mode, the slurry-collecting line 508 is configured to activate the slurry-collecting valve 420 and cause the slurry-collecting nozzle 412 to dispense a continuous flow of one or more flushing agents, such as nitrogen and DI water, during the pre-clean process of the polishing cycle. The flow of DI water and/or nitrogen out of the slurry-collecting nozzle 412 can prevent any contaminants, such as chemicals or used DI water, from entering the slurry-collecting line 508. At the end of the pre-clean process, the cleaning line 510 is configured to activate the waste-collecting valve 422 and cause the cleaning nozzle 410 to draw the chemicals and used DI water from the trough 202. At the same time, the slurry-collecting nozzle 412 continuously flowing nitrogen to dry the collecting gutter 200 and prevent contamination. The cleaning nozzle 410 may flow additional nitrogen into the collecting gutter 200 for drying.

During the polishing process, a substrate is placed in the polishing pad. The slurry-dispending arm 114 dispenses polishing fluids toward the polishing pad while the platen is rotating. The polishing fluids having chemicals and slurries flow to the collecting gutter 200 due to centrifugal force. During the polishing process, the slurry-collecting system may be operation in a slurry-collection mode. The slurry-collecting line 508 is configured to activate the slurry-collecting valve 420 and cause the slurry-collecting nozzle 412 to draw the chemicals and slurries out of the collecting gutter 200. The cleaning line 510 is configured to keep the agent-dispensing valve 424 and the waste-collecting valve 422 closed. At the end of the polishing process, the fluid-dispensing arm 114 stops dispensing the polishing fluids, while the slurry-collecting nozzle 420 prolongs the drawing operation for a predetermined period, such as a few seconds (1-20 seconds). Then, the slurry-collecting line 508 may be switched to the flushing mode again. The slurry-collecting line 508 is configured to switch the slurry-collecting valve 420 to dispense a flow of nitrogen to prevent any contamination in the coming cleaning process.

During the post-cleaning process, the substrate is removed from the polishing pad. The fluid-dispensing arm 114 is configured to dispense a cleaning agent, such as chemicals and DI water, to clean the platen 102 again. The slurry-collecting line 508 and the cleaning line 510 may be operated similarly as during the pre-cleaning process.

In an embodiment, the agent-dispensing valve 424 may be activate at any time during any of the processes to flow DI Water or nitrogen to assist rinsing or drying of the collecting gutter 200.

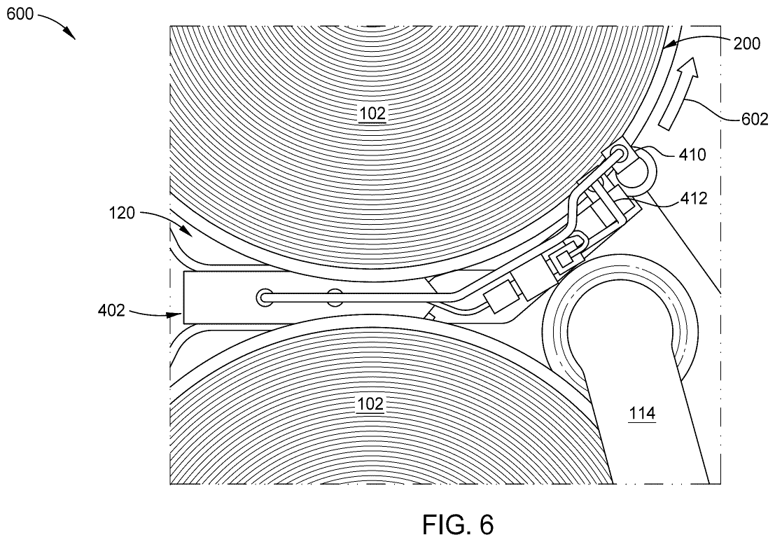

FIG. 6 illustrates a schematic top view of a polishing system 600, according to an embodiment. The polishing system 600 includes two platens 102 arranged sided by side and adjacent to each other to save space. In an embodiment, the upper manifold 402 is disposed between and under the two adjacent platens 102 to save space. The cleaning nozzle 410 and the slurry-collecting nozzle 412 are disposed adjacent to the fluid-dispensing arm 114.

As shown in FIG. 6, the platen 102 rotates in a predetermined direction 602, such as a counterclockwise direction. In an embodiment, the slurry-collecting nozzle 412 is disposed upstream of the rotation direction, while the cleaning nozzle 410 is disposed downstream of the rotation direction. This placement allows the slurry-collecting nozzle 412 to efficiently draw the slurry from the collecting gutter 200.

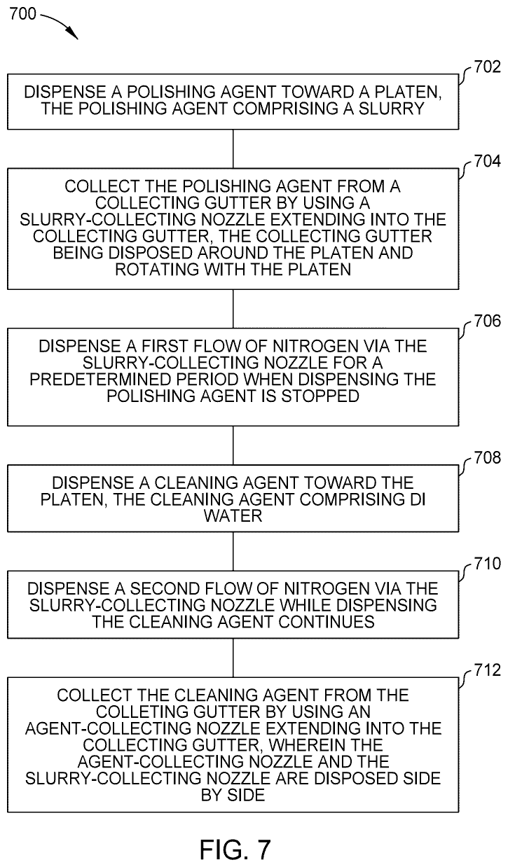

FIG. 7 illustrates a method 700 for operating a polishing system, according to an embodiment. An example of the polishing system is shown in FIG. 1. In an embodiment, the method 700 may be divided into two stages: a polishing stage and a cleaning stage. The polishing stage is configured to polish a substrate with a polishing fluid and includes operations 702 and 704 of the method 700. The cleaning state is configured to clean the platen and the slurry-collection gutter with a cleaning agent and includes operations 706, 708, 710, and 712 of the method 700. As substrates are polished one after another, the polishing stage and the cleaning stage may reiterate many times until all substrates are processed. Thus, operations 702 and 704, although, shown in FIG. 7, appear to occur before operations 708-712, also occur after operations 708-712.

At the start of the method 700 as shown in FIG. 7, the platen 102 has been cleaned and a substrate is disposed on a polishing pad. At operation 702, the fluid-dispensing arm 114 dispenses a polishing fluid toward a platen, which is rotating. The polishing fluid may include a chemical, a slurry, or other polishing agent. At operation 704, the polishing fluid falls into the collecting gutter 200. The slurry-collecting nozzle 412 extends into the collecting gutter 200 and collects the used polishing fluid. The collecting gutter 200 is positioned around the platen 102 and rotating with the platen 102.

At operation 706, the slurry-collecting nozzle 412 is configured to dispense a first flow of nitrogen for a predetermined period when the fluid-dispensing arm 114 stops dispensing the polishing fluid. The predetermined period may be between 1 second to 20 seconds. At operation 708, the polishing process of the substrate has been completed. The substrate has been transferred out of the polishing system 100. The fluid-dispensing arm 114 is configured to dispense a cleaning agent toward the platen 102 to prepare the platen 102 for polishing another substrate. The cleaning agent may include DI water, citric acid, and other suitable chemical. At operation 710, the slurry-collecting nozzle is configured to dispense a second flow of nitrogen while the cleaning agent is being dispensed by the fluid-dispensing arm 114 or before the fluid-dispensing arm 114 stops dispensing the cleaning agent. The second flow of nitrogen can reduce contamination of the slurry-collecting nozzle. At operation 712, the cleaning nozzle 410 extends into the collecting gutter 200 and collects the cleaning agent from the collecting gutter. The cleaning nozzle and the slurry-collecting nozzle are disposed side by side. The cleaning nozzle may also dispense the cleaning agent into the collecting gutter to clean and/dry the collecting gutter.

While the foregoing is directed to embodiments of the present disclosure, other and further embodiments of the disclosure may be devised without departing from the basic scope thereof, and the scope thereof is determined by the claims that follow.

What is claimed is:

1. A polishing system for polishing a substrate comprising:
a polishing platen to support a polishing pad;
a gutter disposed around the polishing platen; and
a slurry-collecting line comprising a slurry-collecting tube coupled with a slurry-collecting valve, the slurry-collecting tube extending into the gutter, the slurry-collecting line being configured to remove slurry from the gutter in a slurry-collecting mode and dispense a flushing agent in a flushing mode.

2. The polishing system of claim 1 further comprising:
a cleaning line comprising a cleaning tube and coupled with one or more valves; the cleaning tube extending into the gutter, the cleaning line being configured to dispense a cleaning agent into the gutter and then remove the cleaning agent out of the gutter.

3. The polishing system of claim 2, wherein the one or more valves comprise a cleaning valve configured to allow the cleaning agent to be delivered to the cleaning tube, and a waste-collecting valve configured to allow the cleaning agent to be suctioned out from the cleaning tube.

4. The polishing system of claim 3, wherein the cleaning agent comprises deionized water, citric acid, or nitrogen, and the flushing agent comprises deionized water and/or nitrogen.

5. The polishing system of claim 3, further comprising:
a base plate disposed under the polishing platen;
an upper manifold attached to a top surface of the base plate; and
a lower manifold attached to a bottom surface of the base plate.

6. The polishing system of claim 5, wherein both the slurry-collecting line and the cleaning line are attached to the upper manifold.

7. The polishing system of claim 6, wherein the cleaning tube and the slurry-collecting tube are disposed side by side in the gutter.

8. The polishing system of claim 6, further comprising a T connector coupling the waste-collecting valve and the cleaning valve, the waste-collecting valve and the cleaning valve being attached to the lower manifold.

9. The polishing system of claim 5, wherein the slurry-collecting line further comprises a controlling line coupled with the slurry-collecting valve and configured to open or close the slurry-collecting valve, the controlling line being coupled with the upper manifold.

10. A polishing system comprising:
a first platen configured to receive a polishing fluid;
a slurry-dispensing arm configured to dispense the polishing fluid toward the first platen;
a slurry-collecting gutter disposed around the first platen;
a base plate disposed under the first platen; and
a dispensing and collecting assembly comprising an upper manifold coupled to a top surface of the base plate and a lower manifold coupled to a bottom surface of the base plate,
wherein the upper manifold comprises a cleaning tube, a slurry-collecting tube, and a slurry-collecting valve coupled to an upper bracket, the slurry-collecting tube being coupled with the slurry-collecting valve; and
wherein the lower manifold comprises a waste-collecting valve and a cleaning valve coupled to a lower bracket, and the cleaning tube is coupled with the waste-collecting valve and the cleaning valve of the lower manifold.

11. The polishing system of claim 10 further comprising a second platen disposed side by side with the first platen, wherein the upper manifold is disposed below and between the first platen and the second platen.

12. The polishing system of claim 10, wherein the cleaning valve are configured to allow a cleaning agent to be delivered to the cleaning tube, and the waste-collecting valve are configured to allow the cleaning agent to be suctioned out from the cleaning tube.

13. The polishing system of claim 12, wherein the cleaning agent comprises deionized water, citric acid, or nitrogen.

14. The polishing system of claim 12, wherein the slurry-collecting tube is configured to allow a flushing agent to be delivered to the slurry-collecting tube, the flushing agent including nitrogen or deionized water.

15. The polishing system of claim 10, wherein the cleaning tube and the slurry-collecting tube extend into a trough of the slurry-collecting gutter.

16. The polishing system of claim 10, wherein the slurry-collecting gutter is configured to rotate in a predetermined direction, the slurry-collecting tube is disposed upstream of the predetermined direction, and the cleaning tube is disposed downstream of the predetermined direction.

17. The polishing system of claim 16,
wherein the upper bracket is disposed substantially horizontally, and the cleaning tube and the slurry-collecting tube are coupled to the upper bracket via a vertical bracket, and
wherein the upper manifold further comprises a holding block configured to secure a slurry-collecting line coupled with the slurry-collecting valve and a upper cleaning line coupled with the cleaning tube.

18. The polishing system of claim 17, wherein the lower manifold further comprises a T connector coupling the waste-collecting valve, the cleaning valve, and a lower cleaning line, the lower cleaning line being coupled with the upper cleaning line via an elbow connector.

19. A method of polishing a substrate, comprising:
dispensing a polishing fluid toward a platen, the polishing fluid comprising a slurry;
flowing the polishing fluid from the platen into a collecting gutter that surrounds and rotates with the platen; and
operating a slurry-collecting line according to a plurality of modes, the slurry-collecting line comprising a collecting tube extending into the collecting gutter, wherein the plurality of the modes comprise:
a slurry-collecting mode in which the slurry-collecting line is configured to remove slurry from the collecting gutter; and
a flushing mode in which the slurry-collecting line is configured to dispense one or more flushing agents into the collecting gutter, the one or more flushing agents comprising deionized water and nitrogen.

20. The method of claim 19, further comprising:
dispensing a cleaning agent into the collecting gutter by a cleaning line comprising a cleaning tube extending into the collecting gutter; and
collecting the cleaning agent from the collecting gutter by using the cleaning tube.
